(19) United States
(12) Patent Application Publication
(10) Pub. No.: US 2009/0303141 A1
(43) Pub. Date: Dec. 10, 2009

(54) REVERBERATION CHAMBER

(75) Inventors: Frederik Kosdikian, Alfortville (FR); Olivier Maurice, Villebon sur Yvette (FR); Olivier Urrea, Gentilly (FR)

Correspondence Address: Perman & Green, LLP, 99 Hawley Lane, Stratford, CT, 06614, US

(73) Assignee: EADS FRANCE, Paris (FR)

(21) Appl. No.: 12/441,181

(22) PCT Filed: Sep. 5, 2007
(86) PCT No.: PCT/FR2007/051871

§ 371 Date: Aug. 6, 2009

(30) Foreign Application Priority Data
Sep. 14, 2006 (FR) 06 53749

(51) Int. Cl. G01R 29/08; H01Q 3/00

(52) U.S. Cl. 343/703; 343/766

(57) ABSTRACT

To construct a reverberation chamber, a chamber provided with reflecting walls contains an antenna and a field stirrer which are placed opposite an object to be tested. By modifying an orientation of a main direction of irradiation from the antenna, a very large number of cavity modes are created inside the chamber, achieving the required variety of possible impingements on the object to be tested, such that the test carried out is as conclusive as possible and the least dependent possible on the dimensions and characteristics of the chamber.

### CROSS-REFERENCE TO RELATED APPLICATIONS

This application is the National Stage of International Application No. PCT/FR2007/051871, International Filing Date 5 Sep. 2007, which designated the United States of America and which International Application was published under PCT Article 21 (2) as WO Publication No. WO2008/031964 A2 and which claims priority to French Application No. 06 53749, filed 14 Sep. 2006, the disclosures of which are incorporated herein by reference in their entireties.

### BACKGROUND

1. Field

The aspects of the disclosed embodiments are directed to an element of a reverberation chamber that can be used in electromagnetic testing.

2. Brief Description of Related Developments

In the field of the electromagnetic testing, especially the testing of electromagnetic compatibility and also the testing of resistance to electromagnetic stress, there are known ways of subjecting devices to electromagnetic excitation and of measuring their behavior. In certain cases, the diffractive properties of electromagnetic waves received by these devices also have to be measured.

In this respect, there is a known electromagnetic testing chamber described in the document EP-B1-1 141733. Such a chamber has typically metallic, reflecting walls. An object to be tested is placed within these walls. In the disclosed embodiments the object to be tested could be a satellite or even an aircraft. Consequently, the dimensions of the chamber could have a height and width of the order of several meters with a length of at least about ten meters. As the case may be, the chamber may be smaller: about one fifth of this size, or even smaller or bigger.

An antenna penetrates the chamber and this antenna is connected, outside the chamber, to a high-frequency signal generator. When fed in this way, the antenna generates radioelectric waves which get propagated and settle fairly quickly into a stationary field in the chamber, according to cavity modes proper to the dimensions of the chamber. The object placed in the chamber is thus subjected to this electromagnetic influence. For each of the values of frequency of the excitation signal, it is possible to measure the behavior of the object tested. It is thus possible to plot the susceptibility of the operation of this device as a function of frequency.

It was noted at an early stage that objects seemed to show high immunity to stress at certain frequency values whereas they showed weaknesses at other frequencies.

In practice, the robustness observed was sometimes illusory. This robustness was to a far greater extent the result of measurements than a representation of what actually happened. Indeed, for certain frequency values, resonance cavity modes that get set up in the chamber lead to excitation nodes at the position in which the object is placed. This gives the illusion that this object is insensitive to these excitations. To resolve the problem, two approaches have been considered:

A first approach envisages the making of very big chambers. Indeed, the greater the chamber, the more likely it is that numerous cavity stationary modes will develop therein, leading to significant electromagnetic excitation at the position of the object. In raising the frequency, the cavity modes can get set up more easily (owing to the shortening of the wave length). Such an approach however has the drawback in which the excitation power to which the object to be tested is subjected depends on the volume of the chamber. The greater the volume of the chamber, the less energy is available at the position of the object to be tested. There is therefore a compromise to be found between the size of the chamber and the excitation power. The excitation power may become prohibitive.

The other approach, described especially in the above-mentioned document, provides for virtually modifying the dimensions of the chamber, either by making the walls of the chamber mobile in orientation and in position through the use of flexible walls or by the use of a metal stirrer.

In the disclosed embodiments it was realized, especially through statistical measurement, that the observed resistance to certain forms of electromagnetic stress could show high dispersion of values from one chamber to another depending on the dimensions of the chamber and the antennas used. In the disclosed embodiments, it was observed by measurements that, ultimately, making geometrical modifications in the walls through the use of a stirrer as recommended in the above document but did not necessarily lead to a sufficiently significant increase in the extensive variety of excitation situations, barring the use of very large-sized stirrers which would considerably reduce the payload volume of the chamber.

### SUMMARY

In the aspects of the disclosed embodiments, the antenna in the chamber is deemed to have has a main direction of emission. To further increase the variety of cavity modes available, it is then planned to modify the main direction of radiation of the antenna in the chamber, i.e. relative to a referential system in which it is mounted. In one approach, the antenna is external to the stirrer. If necessary in this case, the antenna could be separated from the object by a screen or else it could be oriented with its major lobe in a direction opposite that of this screen so that the main direction of irradiation of the antenna preferably cannot attain the object directly. The idea is to obtain at least a certain number of reflections before the wave reaches the object. Acting in this way procures the greatest variety of excited modes while, at the same time, recourse is had to a relatively simple construction chamber (whose walls are preferably fixed).

The aspects of the disclosed embodiments provide a reverberation chamber comprising, within the chamber, a radioelectric antenna, reflective walls and a support of an object subjected in testing to radioelectrical radiation, characterized in that it comprises a radiation stirrer situated in the chamber and means to modify an orientation of a main direction of radiation of the antenna in the chamber.

### BRIEF DESCRIPTION OF THE DRAWINGS

The aspects of the disclosed embodiments will be understood more clearly from the following description and from the accompanying figures. These figures are given purely by way of an indication and in no way restrict the scope of the disclosed embodiments. Of these figures:

FIG. 1 shows a schematic view of an exemplary reverberation chamber according to the disclosed embodiments;

FIG. 2 shows a preferred example of an embodiment of an antenna and a radiation stirrer;

FIG. 3 shows an alternative embodiment of the stirrer.

### DETAILED DESCRIPTION OF THE DISCLOSED EMBODIMENTS

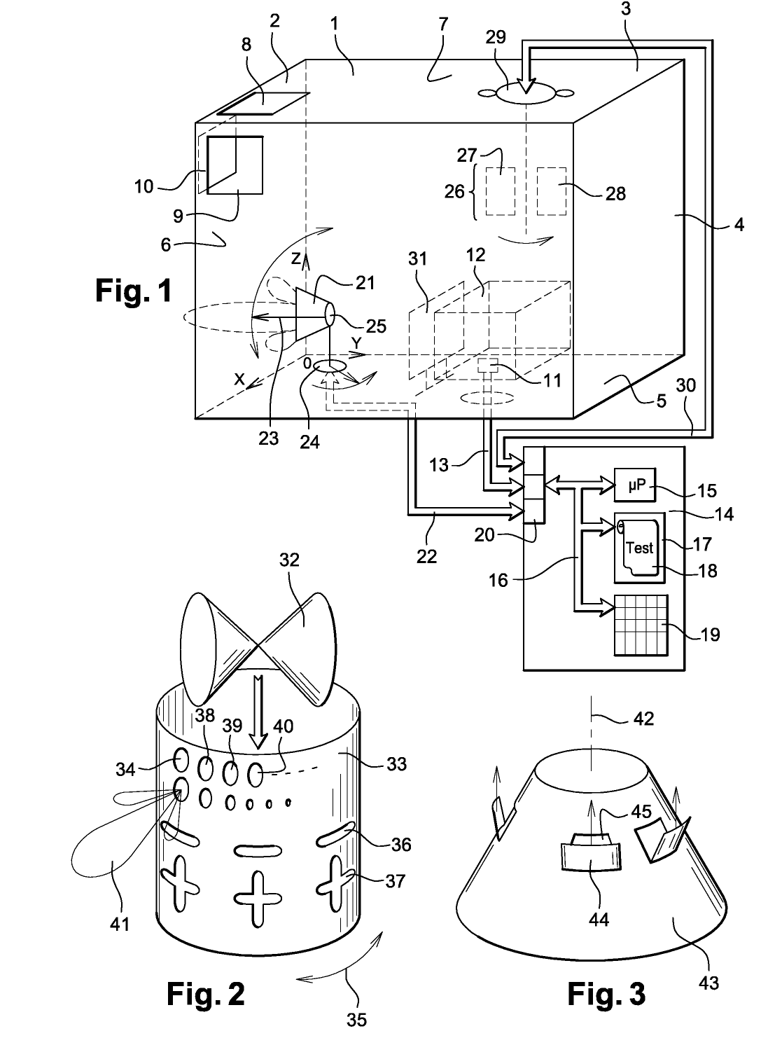

FIG. 1 shows a reverberation chamber 1 according to the aspects of the disclosed embodiments. This chamber 1 has walls such as 2 to 7 which are preferably reflective walls, for example all lined with metallization, especially metal plates such as the plates 8 to 10. The chamber 1 is preferably closed on all its faces. Since the walls 2 to 7 are designed to reflect waves, it is possible rather making a metallization to provide for a gradient of refraction indices to obtain an effect of the same order. The chamber 1 furthermore has a support 11 to support an object 12 subjected to a radiation test. The object 12 may be any unspecified object but preferably an electronic type of object. It may for example be a satellite, an instrument panel of an aircraft, a microcomputer frame or any other apparatus. The object 12 is furthermore connected by a communications and power supply bus 13 to a test management device 14. This device 14, by its principle, will have a microprocessor 15 connected by a bus 16 to a program memory 17 comprising a test program 18, a data memory 19 to record results of measurement or to contain measurement parameters and an interface 20 for communications with the object 12.

The chamber 1 furthermore has a radioelectric antenna 21, herein represented by a horn. The antenna 21 is for exampled powered by the test device 14, by means of a power and control bus 22, itself connected to the interface 20. A radioelectric emitter thus commanded can be physically placed in the chamber 1 or outside.

According to the aspects of the disclosed embodiments, the antenna 21 in one example has a main direction of irradiation 23. In this case, the chamber 1 has a means to modify an orientation of this main direction 23 of radiation of the antenna 21 in the chamber 1. For example, the means of modifying an orientation of the main direction 23 has a first motor 24 to modify an azimuth of the orientation 23 in a plane XOY referenced relative to the walls of the chamber 1. Preferably, these means of modifying will also comprise a second motor 25 which is also controlled by the device 14 to modify an orientation in elevation angle of the main direction of irradiation 23. It may be planned, if necessary, to have translational motions of the position of the horn 21 along each of the three axes OX, OY and OZ.

To improve the variety of distribution of the electromagnetic fields, the chamber 1 furthermore has a stirrer 26, schematically represented herein by two reflection blades 27 and 28. The position of the blades 27 and 28 in orientation and therefore that of the stirrer 26 is controlled by means of a motor 29 connected by a control bus 30 to the interface 20. Preferably, the motors 24, 25 and 29 are stepping type motors and are used to make the objects that they move maintain fixed positions in space within the chamber. In practice, the stirrer 26 is placed above the object 12, hence above the support 11. There is a space between the stirrer 26 and the object 12. The stirrer 26 however can be shifted laterally from the vertical to the centre of the object 12. The stirrer 26 is preferably suspended to the ceiling 2 of the chamber 1.

Preferably, a situation where the antenna 21 does not interact with the walls of the chamber 6 and 4 and irradiates the object 12 directly with its main orientation 23 is avoided. Several approaches are possible. Preferably, the antenna 21 will be placed in an intermediate position between the object 12 and a reflective wall, in this case for example the wall 6. In this case, the main direction of irradiation 23 will be oriented on the whole towards the wall 6. With the motors 24 and 25, the field produced by the antenna 21 will be prevented from directly reaching the object 12. If need be, a screen 31 can be interposed between the antenna 21 and the object 12.

In one embodiment, the stirrer 26 is placed in the chamber in such way that it receives a substantial portion of the radiation reflected by the wall 6 which it subjects to additional reflections whose directions are a function of the position in orientation of this stirrer 26.

Through this form of action, it has been noted that, statistically, the dispersion of the mean values of the field perceived by the receiver is reduced.

At the practical level, the stirrer 26 is a large-sized object. For example, its vertical extension may be about half the height of the chamber 1 measured along the axis Z. Its diameter, since it has to rotate most of the time, may be of the order of 75% of the smallest of the dimensions in width or length of the chamber 1. For example, in a chamber in which the dimensions are 2 m by 3 m for a height of 2 meters, the stirrer may have a diameter of 1.50 m for a height of one meter. In every case, a significant dimension of the stirrer, for example its height or its diameter, will be greater than 20% of one of the dimensions of the chamber, namely its height or its width or its length.

This mode of action means that, in order to bring about variety in the cavity modes created in the chamber 1, there is no need to shift the object 12, an action that would be relatively impossible if this object were to be large-sized, especially if it were to be a satellite. However, it is possible to limit the process to moving a horn 21 in orientation (this is simple) by continuing to make the stirrer 26 rotate. Thus, a positional stirring is obtained.

In a preferred embodiment shown in FIG. 2, the antenna 21 will be replaced by an isotropic antenna 32 situated besides within a confinement cylinder 33 forming the stirrer. The cylinder 33 is for example made of metal. It is preferably reflective for electromagnetic waves. The antenna 32 will for example be borne by the floor 5 of the chamber 2 while the stirrer 33 which surrounds it will be suspended from the ceiling 2. In this case, the support 11 is shifted. Or else the antenna 32 and the stirrer 33 are suspended together. FIG. 2 does not show that the antenna is situated in the cylinder but in practice it is placed therein.

The cylinder 33 is pierced with holes such as 34. Each hole forms a direction of radiation of the antenna. When the stirrer 33 is rotated on itself along the direction of the arrow 35 situated on its shaft carried by the motor 29, the direction of radiation of each hole is modified. The holes may be round (34) or oblong (36) or with arms 37. When they have arms, they may take the shape of a cross with four arms, or even a greater or smaller number or arms. The holes are distributed on the rim of the cylinder 33 in regular series such as for example the holes 34, 38, 39, 40 etc. However, they may be distributed on the rim of the cylinder in a random series, the sizes, the distances between holes and the shapes of the holes being random. The sizes of the holes and the distances between them may furthermore be identical or progressive so that, by their progressivity, they form a major lobe 41 of irradiation which will rotate with the stirrer 33. In practice, the stirrer takes the form of a cylinder with a diameter of one meter and a height of 1.5 meters.

The antenna 32, whether isotropic or not, is excited by monofrequency signals whose frequency varies, preferably by steps, from 150 Megahertz to 10 Gigahertz. These frequency values or this range correspond to the range for which the object 12 to be tested has to be characterized. With this preferred solution, the stirrer 33 is placed vertically above the object 12. As a variant, the axis of rotation of the stirrer 33, inclined otherwise than to the vertical, passes through the object 12.

In order to avoid symmetries which are at the core of the absences or deficits of excitation encountered, and of the dispersion in values between chambers, a preferred embodiment places the rotation shaft 42 (FIG. 1) of the stirrer 26 or 33 at a third of each of the dimensions of width OX or length OY of the chamber 1. Similarly, the centre of the stirrer 33 and therefore the antenna 32 will also be placed at a third of the height OZ starting from the top or starting from the bottom. In thus preventing the stirrer from being placed in a median position, the disclosed embodiments avert symmetries and prompt the creation of a greater number of cavity modes.

In the depiction of FIG. 2, the stirrer 33 is voluminous and may contain the antenna 32. This antenna 32 may have the shape of an isotropic antenna or the shape of a horn with a major lobe 23 as shown on FIG. 1. And in this case, the antenna may also rotate independently of the stirrer 33.

In another embodiment, shown in FIG. 3, the stirrer may be formed by a horn 43 pierced with holes of the same type as the stirrer 33. The stirrer 43 or 33 may also possess deflectors 44 situated so as to be facing certain particular holes 45 of its truncated or cylindrical surfaces. These deflectors are also used to create particular cavity modes.

The ultimate aim therefore is not to provide for electromagnetic excitation distributed in every direction with the same power but rather, at the position of the object 12, to foresee stresses applied this object 12 along the greatest possible variety of angles of incidence, (preferably an exhaustive range of angles of incidence and with significant power) and good statistics less dependent on the characteristics of the chamber. The disclosed embodiments, by causing the source to rotate and the stirrer to rotate about the source, creates a stirring that is simultaneously mechanical and positional.

What is claimed is:

1. Reverberation chamber comprising, within the chamber, a radioelectric antenna comprising:
a main direction of radiations,
reflective walls,
a support of an object subjected in testing to radioelectric radiation, and
a radiation stirrer situated in the chamber,
characterized in that it comprises motors to modify the orientation of the main direction of radiation of the antenna in the chamber.

2. Chamber according to claim 1, wherein the motors comprise motors to modify the orientation of the main direction in rotation, in azimuth and/or in elevation, relative to the plane of the chamber.

3. Chamber according to claim 1, wherein the stirrer comprises a reflecting cylinder.

4. Chamber according to claim 3, further comprising that the cylinder is pierced with holes.

5. Chamber according to claim 4, further comprising that the holes are round, and/or oblongs and/or with arms and are distributed on the rim of the cylinder in regular or progressive or random series, and in identical or progressive sizes, as a function of the range of frequency of the radioelectric signals to be characterized.

6. Chamber according to claim 1, wherein the motors comprise means to modify the main direction step by step.

7. Chamber according to claim 1, wherein the stirrer possesses a dimension that is greater than 20% of one of the dimensions of the chamber.

8. Chamber according to one of the claim 1, further comprising that the stirrer is supported by a vertical shaft.

9. Chamber according claim 1, further comprising that the center of the stirrer is placed at a third of each of the dimensions of the chamber.

10. Chamber according claim 1, further comprising that the antenna is situated in the stirrer.

11. Chamber according claim 1, further comprising that the stirrer has deflectors fixed to a reflective surface.

12. Chamber according to claim 1, wherein the object subjected to the test is an electronic apparatus.

13. Chamber according to claim 1, further comprising a metal screen interposed between the antenna and the object.
